(19) United States
(12) Patent Application Publication
(10) Pub. No.: US 2007/0169688 A1
(43) Pub. Date: Jul. 26, 2007

(54) Method for manufacturing silicon wafer

(75) Inventors: Sung Ho Yoon, Daejeon-Shi (KR); So Ik Bae, Daejeon-Shi (KR); Young Hee Mun, Gumi-Shi (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: SILTRON INC., Gyeongsangbuk-do (KR)

(21) Appl. No.: 11/651,695

(22) Filed: Jan. 9, 2007

Related U.S. Application Data
(62) Division of application No. 10/973,545, filed on Oct. 26, 2004.

(30) Foreign Application Priority Data
May 10, 2004 (KR) 2004-32633

(51) Int. Cl. C30B 25/00; C30B 23/00; C30B 28/14

(52) U.S. Cl. 117/94; 117/97; 117/105

(57) ABSTRACT

A method for manufacturing a high quality annealed wafer which has both a uniform and high density bulk micro defect (BMD) in a bulk zone disposed between front and rear denuded zones (DZ), which increases the effect of gettering metal impurities such as Fe, Cu and etc., and which provides a defect free zone in the active region of device.

### CROSS-REFERENCE TO RELATED APPLICATION

This is a division of copending, commonly assigned application Ser. No. 10/973,545 filed Oct. 26, 2004, the disclosure of which is incorporated herein by reference.

### BACKGROUND

1. Technical Field

A silicon wafer and a method for manufacturing the same are disclosed. The disclosed wafer has a high density and uniform bulk micro defect (BMD) concentration in a bulk area of the wafer disposed between front and rear denuded zones (DZ).

2. Discussion of the Related Art

As semiconductor devices become ultra-minute with sizes under 0.1 μm and more highly integrated, the silicon wafers from which these devices are made have become larger, in excess of 300 mm. While the development of large wafers provides numerous advantages, defects in the large wafers must be avoided.

Specifically, manufacturers are required to provide a “non-defect” layer in an active region of the wafer or the resulting semiconductor device. Manufacturers have also been required by customers to effectively remove impurities such as metal particles that can be generated during the manufacturing process. Further, manufacturers have been required to increase the bulk micro defect “BMD” density which consists primarily of oxygen precipitates and the bulk or oxidation stacking fault in the bulk area beneath the active region of the resulting device.

In achieving these goals, numerous defects must be eliminated, manipulated or controlled. Of the numerous defects that may be created, crystal originated pits (COP), flow pattern defect (FPD), laser scattering tomography defect (LSTD) and a slip occurrence are of primary interest.

COP appears on the surface layer of a wafer is of a size in the range of 0.09˜0.12 μm and can be observed with a SP1-TBI scanner and by re-processing with a standard cleaning (SC1) solution. COP appears as a pit on the wafer. COP is a crystal defect induced during the crystal growing process. FPD is related to the oxide film, is a defect with a ripple shape, and is detected being etched selectively by using an etching solution of group of potassium bichromic-acid, hydrofluoric acid (HF). FPD may be confirmed with a microscope. LSTD, a defect detected by a laser scattering tomography, has been known as a micro defect generated during a crystal growing process. “Slip” occurs when significant temperature gradients are present within the wafer during heat treatments and from differences in coefficients of heat expansion of the silicon wafer and the silicon carbide boat used during heat processing of the wafer. COP is the most influential defect component and FPD density and LSTD may be used to confirm COP directly or indirectly.

If a customer proposes a COP free zone up to a 10 μm depth from the surface of the water, a SP1-TBI or a method of etching process may be used to detect defects on the surface of the wafer, and LSTD can be monitored up to a 5 μm depth. As a result, a wafer manufacturer confirms COP defects, or the lack thereof, indirectly with a combination of the SP1-TBI and LSTD with additional polishing up to a 10 μm depth.

There are many oxygen impurities found in silicon wafers produced by processing single-crystalline silicon, pulled and grown by a Czochralski CZ method. The oxygen impurities become oxygen precipitates which generates dislocations or defects. When the oxygen precipitates are on the surface of the wafer, they increase leakage current and degrade an oxide film inside-pressure, which are both disadvantageous characteristics for a semiconductor device.

Furthermore, silicon wafers must include a denuded zone (DZ) from a surface or edge of the wafer to a predetermined depth, in which there is no dislocation, stacking defect or oxygen precipitates. DZs are typically required at the front and the rear of the wafer. To achieve these objectives, several methods for manufacturing silicon wafers are provided.

First, it has been attempted to make a non-defect zone in an active region of device by manufacturing a pure single-crystalline silicon without defects when producing a silicon ingot for fabricating the silicon wafer. However, in this case, the oxygen precipitates are reduced in a bulk zone, and therefore the BMD density is also low. Also manufacturing pure single-crystalline silicon is costly.

Second, to provide a non-defect zone in the active region of the semiconductor device, a method exists for making an epitaxial-type wafer grown for an epitaxial layer by using a chemical vapor deposition (CVD) method on the silicon wafer. While, this method has improved techniques over the pure single-crystalline silicon manufacturing method discussed above and the annealed wafer manufacturing method discussed below, it is very costly.

Third, an annealing method is used for making non-defect zones in the active region of semiconductor devices. In this method, by removing the crystal originated pit generated during crystal growth by way of a heat treatment process, the COP is eliminated from the active region of semiconductor device. Also, DZ zones without oxygen precipitates can be provided up to a predetermined depth by way of an oxygen out-diffusion in the surface area. Moreover, annealing can effectively eliminate impurities such as a metal by increasing BMD density, the oxygen precipitates in the bulk zone.

However, current annealing techniques require numerous adjustments to the gas atmosphere, temperature ramp-up/down rates and heat treatment temperatures/times, all of which make control of the process very difficult, costly and unreliable. Consequently, current annealing processes generate defects such as slip during the high temperature processes, or the annealed wafer can't be manufactured with a uniform and sufficient non-defect zone and high BMD density. Therefore, an improved annealing type process is urgently needed.

### SUMMARY OF THE DISCLOSURE

A silicon wafer is disclosed that has a uniform and sufficient front and rear denuded zones (DZs) and a COP free zone in an active region of the wafer. The disclosed wafer also has a high density of BMDs in the bulk zone of the wafer disposed between the front end rear DZs.

A method for manufacturing a silicon wafer on the order of 300 mm that controls a slip due to a high temperature process used to remove defects in the wafer, provides a uniform and a sufficient DZ and a COP free zone in an active region of wafer, and provides a high density of BMDs in the bulk zone.

One disclosed silicon wafer comprises: a first denuded zone (DZ) formed over a predetermined depth from a surface of a front side of the wafer, without a crystal originated pit (COP) defect; a second denuded zone (DZ) formed over a predetermined depth from a surface of a rear side of the wafer, without a crystal originated pit (COP) defect; and a bulk zone formed between the first and second denuded zones, in which a concentration profile of bulk micro defects (BMD) is uniform from the front side towards the rear side of the wafer; and wherein the silicon wafer is doped with nitrogen in a concentration ranging from about 1×10¹² atoms/cm³ to about 1×10¹⁴ atoms/cm³.

Preferably, the concentration of the BMDs is in the range of from about 1.0×10⁸ to about 1.0×10¹⁰ ea/cm³ or defects/cm³ in the bulk zone between the first and second denuded zones.

Preferably, depths or widths of the first and second denuded zone are within the range of from about 5 μm to about 40 μm respectively from the front and the rear sides of the wafer.

Furthermore, a method of manufacturing a silicon wafer is disclosed that comprises: (a) preparing a silicon wafer having a front side, a rear side, and a zone disposed between the front and rear sides; (b) loading the silicon wafer on a heat treatment apparatus heated to a first temperature; (c) pre-heating the silicon wafer to the first temperature for a predetermined time; (d) raising the temperature of the heat treatment apparatus to a second higher temperature at a first temperature ramp-up rate; (e) raising the temperature of the heat treatment apparatus up to a third still higher temperature higher at a second temperature ramp-up rate; (f) raising the temperature of the heat treatment apparatus up to a fourth still higher temperature higher at a third temperature ramp-up rate; (g) heating the silicon wafer at the fourth temperature by maintaining the fourth temperature for a predetermined time; and (h) reducing the temperature of the heat treatment apparatus towards the first temperature; wherein the second temperature ramp-up rate is smaller than the first temperature ramp-up rate; parts (c), and (f) through (h) are carried out in atmosphere of inert gas; and parts (d) and (e) are carried out in atmosphere of hydrogen.

Preferably, the preparing of the silicon wafer includes the steps of: dipping a seed crystal in a silicon melt and growing a single-crystalline silicon by pulling up the seed crystal while adjusting a crystal growing speed and a temperature gradient along a growing axis at a boundary of solid and liquid phase boundary; slicing the grown single-crystalline silicon into shapes of wafers; and removing slicing damage generated from slicing and rounding sides of the sliced wafer or etching a surface of the sliced wafer; wherein the single-crystalline silicon is grown with nitrogen doped in concentration ranging from about 1×10¹² atoms/cm³ to about 1×10¹⁴ atoms/cm³ so as to increase precipitated oxygen.

After part (h), the disclosed method preferably further comprises one or more of: polishing the surface of the silicon wafer; making the surface of the silicon wafer specular; and cleaning the silicon wafer.

Preferably, the first temperature is about 500° C., the second temperature is about 950° C., the third temperature is about 1100° C. and the fourth temperature is about 1200° C.

Preferably, the first temperature ramp-up rate is about 10° C./min, and the second temperature ramp-up rate is about 5° C./min.

Preferably, the third temperature ramp-up rate is from about 0.1 to about 5° C./min.

Part (g) is preferred to perform for a time period ranging from about 1 to about 120 minutes at the fourth temperature.

Preferably, part (h) includes: reducing the temperature down to about the third temperature at a first temperature ramp-down rate; reducing the temperature down to about the second temperature at a second temperature ramp-down rate; and reducing the temperature down to about the first temperature at a third temperature ramp-down rate.

Preferably, the third temperature ramp-down rate is larger than the second temperature ramp-down rate.

Preferably, the first temperature ramp-down rate is from about 0.1 to about 5° C./min.

Preferably, the second temperature ramp-down rate is about 5° C./min and the third temperature ramp-down rate is about 10° C./min.

### BRIEF DESCRIPTION OF THE DRAWINGS

FIG. 1 is a diagram illustrating processes for manufacturing a silicon wafer in accordance with one disclosed embodiment.

FIG. 2 graphically illustrates a heat treatment process in accordance with one disclosed embodiment.

FIGS. 3a and 3b are bar graphs illustrating the relationship between the number of localized light scattering (LLS) and LLS size according to whether or not nitrogen is present.

FIG. 4 graphically illustrates the relationship between an average value of a flow pattern defect (FPD) and a nitrogen doping concentration.

FIG. 5 is a diagram illustrating a gate oxide integrity (GOI) monitoring result according to a heat treatment temperature of a nitrogen-doped wafer.

FIG. 6 is a diagram illustrating a near surface micro defect monitoring result according to a heat treatment temperature.

FIGS. 7a and 7b graphically illustrates variations in zone depth without COPs by varying heat treatment time of a nitrogen-doped wafer as measured by LLS.

FIGS. 8a and 8b graphically illustrate the relationship between denuded zone depth and bulk micro defect density according to a temperature ramp-up rate.

FIG. 9 graphically illustrates the relationship between the variations in denuded zone depth and bulk micro defect density according to oxygen concentration.

FIG. 10 graphically illustrates the relationship between zone depth without COP and oxygen concentration of a nitrogen-doped silicon wafer.

FIGS. 11a and 11b graphically illustrates the relationship between overall slip length and a temperature ramp-up rate.

FIG. 12 are diagrams illustrating procedures of controlling slip by way of oxygen precipitates in a silicon wafer.

FIG. 13 graphically illustrates the relationship between slip length and oxygen concentration.

FIG. 14 is a diagram illustrating a spreaded depth of slip on a surface after a heat treatment process.

FIGS. 15a and 15b graphically illustrates the relationship between resistivity, depth from the wafer surface, according to the gas atmosphere.

FIG. 16 graphically illustrates the BMD concentration profile of a disclosed silicon wafer manufactured with the techniques disclosed herein.

### DETAILED DESCRIPTION OF THE PRESENTLY PREFERRED EMBODIMENTS

Disclosed methods for manufacturing silicon wafers will now be described in detail with reference to the accompanying drawings.

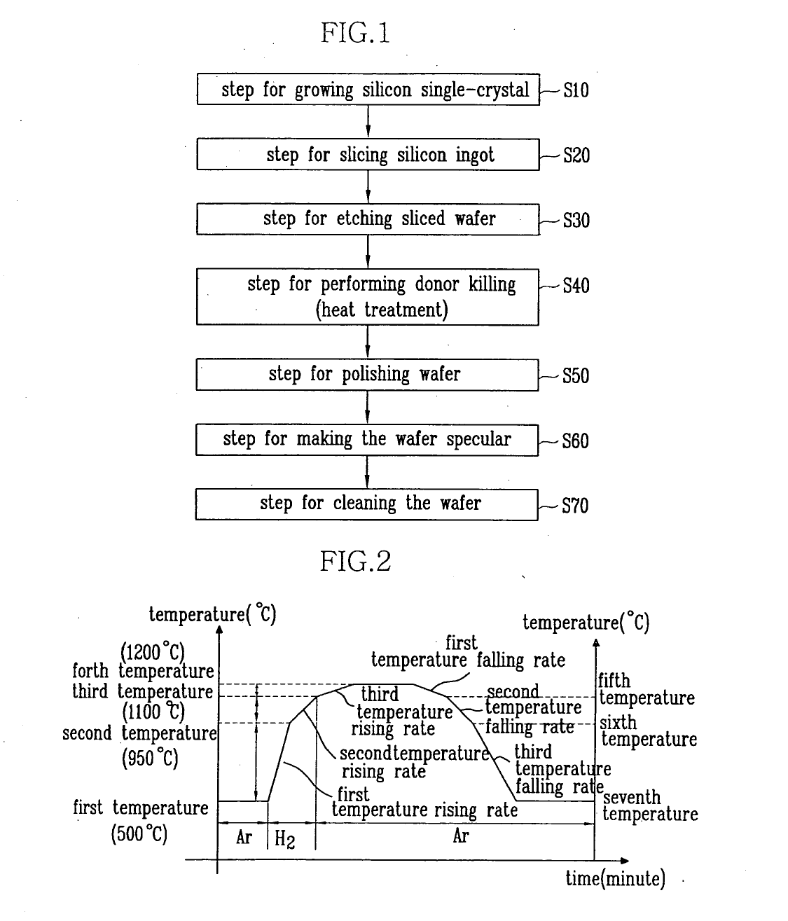

Referring to FIG. 1, a single-crystalline silicon is grown using a Czochralski CZ method (S10). After dipping a seed crystal into a silicon melt, the crystal is slowly pulled and grown. The nitrogen is to be doped in a silicon single-crystalline ingot during the crystal growing. The nitrogen doping concentration is preferably about 1×10¹² atoms/cm³ through 1×10¹⁴ atoms/cm³.

Next, the ingot is sliced into shapes of wafer (S20).

Slicing damages occurred in performing the slicing process are removed, and an etching process is carried out for etching a surface or rounding a side of the sliced wafer (S30).

A donor killing process is the performed (S30), in which oxygen is generated from a crystal growing step included in a silicon wafer which includes oxygen precipitates from a heat treatment process. That is, approximately 10¹⁶ atoms/cm³ of oxygen atoms among the approximately 10¹⁸ atoms/cm³ of oxygen atoms included in crystal growing step of the silicon wafer donate an electron by way of collecting a plurality of oxygen atoms during a single-crystal peak cooling process and then they become like donors. It is difficult to get a target resistance ratio due to those electron donors even though adding a dopant for balancing the resistance ratio of wafer. Therefore, the donor killing process is carried out to make the oxygen generated from the crystal growing step into the oxygen precipitates to prevent the oxygen from acting as a donor (S40). The donor killing process includes a heat treatment.

Next, the surface of the silicon wafer (S50) is polished, and the surface of the silicon wafer is made specular (S60) and the silicon wafer is cleaned (S70). The silicon wafer is then packaged.

Part (S10) for growing the single-crystalline silicon will be briefly described. First, a necking step is carried out to grow a thin and long crystal from the seed crystal, and shouldering step is followed to make the single-crystalline silicon a target diameter by growing it in an outward direction to increase the diameter of the crystal. A crystal with a constant diameter is grown after completing the shouldering step, which is referred to as a body growing step. The body growing step is performed over a predetermined length, as the diameter of the crystal is being increased. The crystal growing step is completed by carrying out a tailing process step which separates the crystal from the silicon melt. The crystal growing process is carried out at a hot zone. A grow is disposed between the silicon melt and the ingot contact at the time that the silicon melt is growing to the single-crystal ingot. The grower includes a crucible, a heater, a thermostat structure, an ingot pulling apparatus, a pedestal and so on.

The silicon wafer is fabricated by performing processes such as cutting off, polishing, and cleaning up the nitrogen-doped silicon ingot under a predetermined concentration.

FIG. 2 is a diagram illustrating a heat treatment process. The heat treatment apparatus (furnace) can be a readily available commercial apparatus.

Referring to FIG. 2, the silicon wafer fabricated from slicing ingot grown into crystal growth by way of a Czochralski CZ method (FIG. 1) is loaded at the heat treatment equipment (diffusion furnace) at an inert gas atmosphere, for instance, an argon gas atmosphere. The temperature for the heat treatment apparatus is set at a first temperature of about 500° C. Setting the first temperature too high can cause “slip” due to a heat stress due to a temperature difference between a wafer edge and the wafer center. To avoid slip, the silicon wafer is pre-heated and maintained for a predetermined time at the first temperature in the heat treatment apparatus.

The gas atmosphere in the heat treatment apparatus is changed to a hydrogen gas atmosphere, the temperature in the heat treatment apparatus is increased to a second temperature (for example, about 950° C.) at about first temperature ramp-up rate (for example, about 10° C./min).

When the temperature in the heat treatment apparatus has risen to the target second temperature, the temperature in the heat treatment apparatus is increased to a third temperature (for example, about 1100° C.) using a second temperature ramp-up rate (for example, about 5° C./min). The second temperature ramp-up rate is preferably smaller than the first temperature ramp-up rate to avoid slip occurrence. When increasing the temperature, the second ramp-up temperature rate must be decreased or reduced to slow the heating. Thus, the second temperature ramp-up rate must be smaller than that of the first temperature ramp-up rate to control slip due to any temperature variation between the wafer center and its edge.

When the temperature in the heat treatment apparatus is heated up to the target third temperature, the gas atmosphere in the heat treatment apparatus is changed to the inert gas atmosphere, for instance, an argon gas atmosphere, and the temperature in the heat treatment apparatus is risen to the fourth temperature (for example, about 1200° C.) at a third temperature ramp-up rate (for example, in the range of from about 0.1 to about 5° C./min)

When the temperature in the heat treatment apparatus is heated up to the target fourth temperature, the apparatus carries out the heat treatment at a high temperature by maintaining the fourth temperature for a time period ranging from about 1 to about 120 minutes. It is preferable to maintain the apparatus at the fourth temperature for about 60 minutes for assuring a suitable level of denuded zone depth and BMD density. If the fourth temperature is maintained for over 120 minutes, a zone without COP is deeper, but the diffusion furnace can't be used for a long time and productivity is decreased.

The temperature is then reduced down to a fifth temperature with the first temperature ramp-down rate (for example, in the range of from about 0.1 to about 5° C./min). The fifth temperature is preferably about the same as the third temperature.

After the temperature has been reduced to the fifth temperature, it is reduced again to a sixth temperature at the second temperature ramp-down rate (for example, about 5° C./min). The sixth temperature is preferably about the same as the second temperature.

After the temperature has been reduced to the sixth temperature, it is reduced further to a seventh temperature at a the third temperature ramp-down rate (for example, about 10° C./min). The seventh temperature is preferably about the same as the first temperature. The third temperature ramp-down rate is preferable larger than that of the second temperature.

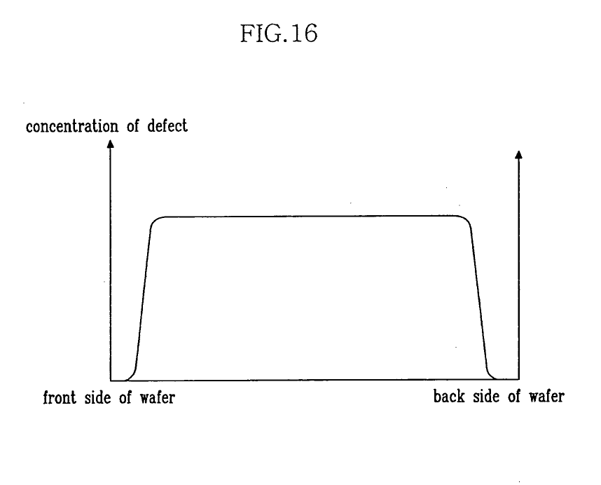

FIG. 16 graphically illustrates defect concentration profile of a silicon wafer manufactured by a disclosed method. Referring to FIG. 16, a first denuded zone (for example, a depth in the range of from about 5 μm to about 40 μm from the wafer edge surface) without a crystal originated pit (COP) defect is formed from the wafer front edge to a predetermined depth from the front edge. A second denuded zone (for example, the depth in the range of from about 5 μm to about 40 μm from the wafer edge surface) without COP defect is formed from the wafer rear edge to a predetermined depth. A bulk zone is formed between the first and the second denuded zone, in which the concentration profile of the bulk micro defect (BMD) is uniformly maintained between the first and second denuded 3 ones. The BMD concentration between the first and the second denuded zone has the range of from about 1.0×10⁸ to about 1.0×10¹⁰ ea/cm³ and has a sufficient and uniform concentration capable of acting as a gettering site throughout the bulk zone.

The heat treatment process of FIG. 1 can lead to get a defect concentration profile of the silicon wafer described with reference to FIG. 16. Although there can be variations in heat treatment temperatures, heat treatment times, temperature ramp-up rates, and temperature ramp-down rates, kinds of gas atmosphere, flux, a mixed rate, and so forth, FIG. 1 provides a general guide for obtaining a sufficient and uniform defect concentration profile in the bulk zone by using the disclosed nitrogen doping and the heat treatment.

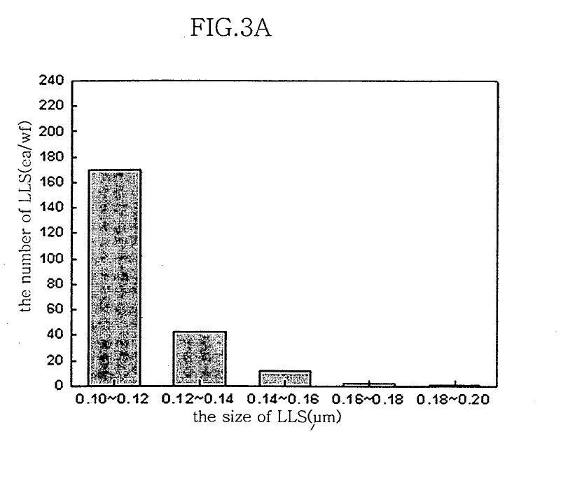

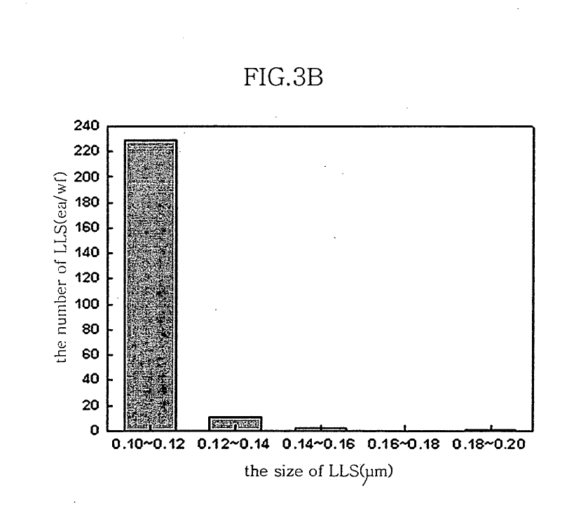

FIGS. 3a and 3b are diagrams illustrating the number of localized light scattering (LLS) by size regardless of whether nitrogen doping has been carved out. FIG. 3a describes a case without nitrogen while growing the ingot at a constant pulling speed (about 1.4 mm/min), and FIG. 3b shows another case with nitrogen in a concentration of about 5×10¹³ atoms/cm³ while growing the ingot at a constant pulling speed (about 1.4 mm/min). The number of LLS has been measured by using an apparatus of KLA-Tencor Surfscan SP1. As illustrated in FIG. 3b, a minute particle by a size below 0.12 μm is increased by doping the nitrogen to the single-crystalline silicon, while a large particle by a size over 0.12 μm is decreased. The results are achieved by increasing the minute oxygen precipitates at the core by decreasing the energy necessary for core generation in the silicon matrix by way of adding a heterogeneous nitrogen atom to a homogeneous single-crystalline silicon. It is possible to simply remove the particles during the heat treatment at a high temperature by increasing the number of minute particles and decreasing the number of large particles by way of adding the nitrogen, an impurity for the silicon to single-crystalline silicon. Accordingly, it is preferred to add the nitrogen during a step of growing the silicon crystal for providing a sufficient denuded zones and a zone without COPs.

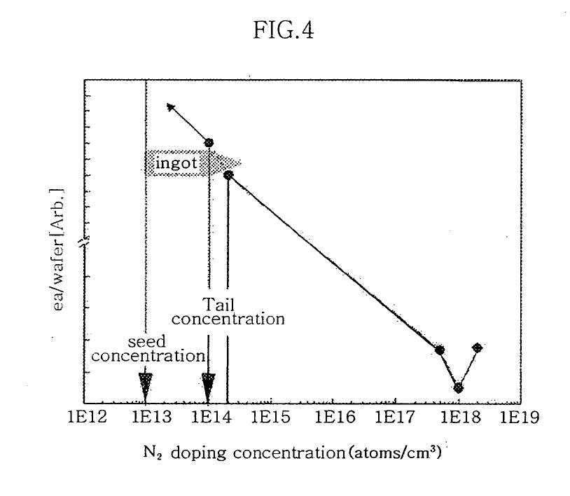

FIG. 4 graphically illustrates an average value of a flow pattern defect (FPD) according to a nitrogen doping concentration. During this, the ingot is grown at the pulling speed of about 1.4 mm/min. FPD is a defect capable of being observed by a microscope by way of performing a Secco etching process (for instance, by using a solution mixed with K₂Cr₂O₇ and HF at a predetermined ratio) for about 30 minutes in a zone with COP, a defect generated during crystal growing step. Referring to FIG. 4, while the nitrogen doping concentration is decreased, an average FPD density is increased for each wafer. That is, in this zone, as the nitrogen concentration increases, FPD decreases. However, as the nitrogen concentration increases, a nitrogen induced large defect (NiLD) is generated. In a concentration of over 5×10¹⁴ atoms/cm³, FPD is low and NiLD is present, the crystal defect due to the nitrogen on the whole wafer is generated.

Therefore, during manufacturing a silicon ingot, it is not advantageous to cause a crystal defect by nitrogen by way of increasing the nitrogen concentration over 1×10¹⁴ atoms/cm³. It is preferred to control the nitrogen concentration below 1×10¹⁴ atoms/cm³ when adding the nitrogen to the single-crystalline silicon for manufacturing an annealed wafer.

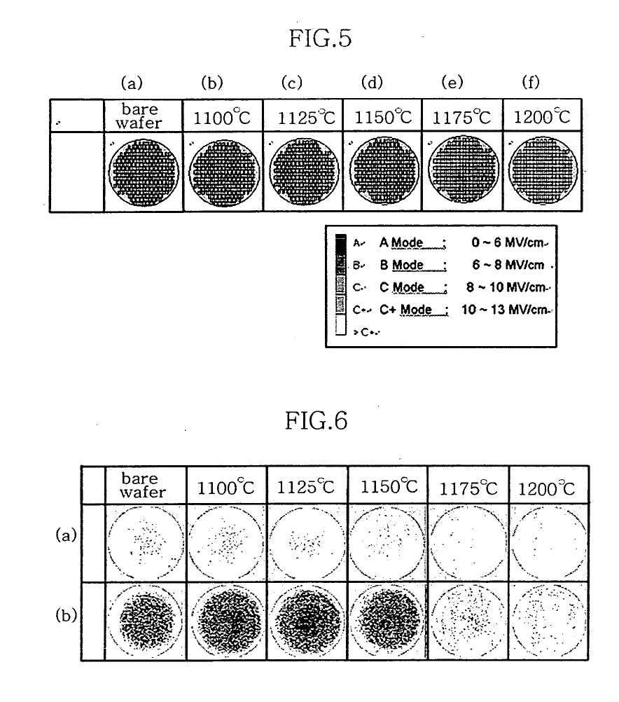

FIG. 5 is a diagram illustrating a gate oxide integrity (GOI) monitoring result according to a heat treatment temperature of a nitrogen-doped wafer. The GOI estimation is to indirectly confirm a fail rate of a semiconductor device. Referring to FIG. 5, an A-mode fail is caused by applying an electric field of 0˜6 MV/cm, a B-mode fail is caused by applying the electric field of 6˜8 MV/cm, a C-mode fail is caused by applying the electric field of 8˜10 MV/cm, and a C+-mode fail is caused by applying the electric field of 10˜13 MV/cm. In general, the B-mode fail has been known to be caused by COP. After performing a heat treatment process for a silicon wafer, GOI is estimated through polishing from the surface to the depth of 6 μm. The heat treatment process is performed according to the embodiment discussed above and described in FIG. 1.

The conditions of the heat treatment include the: changing an atmosphere in a diffusion furnace to an argon gas atmosphere, putting a silicon wafer into the diffusion furnace, and pre-heating and maintaining the silicon wafer at the temperature of 500° C.; heating up the temperature up to 950° C. at a heating rate of about 10° C./min after changing the gas atmosphere in the diffusion furnace to a hydrogen H2 atmosphere; heating up the temperature up to 1100° C. at a heating rate of 5° C./min; heating up the temperature up to about 1200° C. at a heating rate of about 1° C./min after hanging the gas atmosphere in the diffusion furnace to an argon atmosphere; maintaining it at the temperature of about 1200° C. for about 60 minutes; reducing the temperature to about 1100° C. at a cooling rate of about 1° C./min; reducing the temperature to about 950° C. at a cooling rate of about 5° C./min; and reducing the temperature to about 500° C. at a cooling rate of about 10° C./min. The GOI estimation is performed after setting the thickness of the oxide film at 120 Å, the thickness of the polysilicon at 1000 Å, and a transistor area at 0.2 cm² and then using an HP4156A, as a breakdown voltage measuring equipment. As shown in the part (a) in FIG. 5, in case of a bare wafer before the heating treatment, a fail has been occurred in the whole area of wafer. Here, the fail is due to the COP on the wafer surface according to crystal characteristics of the bare wafer without performing the heat treatment, but as the heat treatment temperature is being increased, as shown in the parts (b) to (f) in FIG. 5, the COP on the wafer surface is easily removed and thus a fail rate is gradually decreased. As a result of this, there are few failures at the heat treatment temperature of about 1200° C. That is, the COP, a void type defect of the bare wafer without performing the heat treatment is completely removed by the heat treatment in a high temperature, and the oxygen precipitates on the surface is also dissolved at the high temperature.

FIG. 6 is a diagram illustrating a near surface micro defect NSMD monitoring result according to a heat treatment temperature. The part (a) in FIG. 6 shows a measured result of NSMD by polishing by the depth of 1 μm, and the part (b) in FIG. 6 shows a measured result of NSMD by polishing by the depth of 5 μm. The NSMD is monitored by MO601 equipment made by Mitsui-Mining company in Japan. As shown in the part (a) in FIG. 6, in the case of polishing to a depth of 1 μm, COP rarely occurs shown on the surface. However, as shown in the part (b) in FIG. 6, in case of polishing to the depth of 5 μm COP is not completely removed after the heat treatment at 1150° C., but is completely removed only at the temperature over 1175° C. That is, in order to assure the predetermined depth without the COP from the surface to the depth of 5 μm, it is preferred to perform the heat treatment at 1175° C. or higher. On the other hand, as described in FIG. 5, it is preferred to perform the heat treatment at the temperature of about 1200° C. for minimizing the fail rate of the GOI due to the COP.

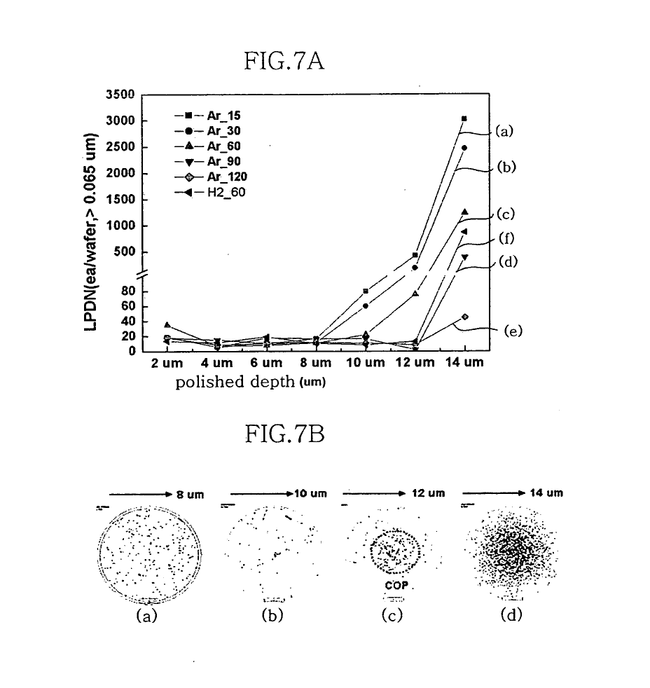

FIGS. 7a and 7b are diagrams illustrating results monitoring variation of a zone depth without COP according to a nitrogen-doped wafer by way of variation of LLS. The parts (a), (b), (c), (d), and (e) in FIG. 7a show cases of performing the heat treatment for 15, 30, 60, 90, 120 minutes, respectively, under an argon atmosphere. And the part (f) shows a case of performing the heat treatment for 60 minutes at a hydrogen (H2) atmosphere. The part (a) in FIG. 7b shows LPDN distribution of a case of polishing to 8 μm from the wafer surface, the part (b) is a case of polishing to 10 μm, the part (c) is a case of polishing to 12 μm, and the part (d) is a case of polishing to 14 μm.

Here, the temperature of the heat treatment is fixed at about 1200° C. The heat treatment is performed by the same condition as the case illustrated with reference to FIG. 5. As shown in FIGS. 7a and 7b, in case of polishing an annealed wafer, LLS is remarkably increased at a specific depth from the surface. It shows that the COP is removed by the heat treatment in a high temperature up to a specific depth from the wafer surface, but reflects crystal characteristics of the bare wafer without removing COP at over a specific depth. As illustrated in FIG. 7, as the heat treatment time at the temperature of 1200° C. is being increased, the area where the LLS is remarkably increased is gradually deepened. As a result, the depth of the area without the COP is also deepened. Additionally, in case of the same heat treatment time, the heat treatment process in a hydrogen atmosphere represents a superior COP removing efficiency to the heat treatment in an argon atmosphere. Because oxygen on the internal wall surface is removed more easily during a hydrogen heat treatment than during an argon heat treatment process, the COP, a void type defect, can be easily removed. However, in case of using hydrogen gas, it is superior to an argon gas at the side of the depth of zone without COP, but it is advantageous to use argon gas at the side of a metal contamination by etching a Quartz tube used for the heat treatment process.

Furthermore, as described in FIGS. 7a and 7b, it is preferred to set the heat treatment time by 60 minutes at the temperature of about 1200° C. for assuring the zone depth without COP to at least 10 μm. Although it is preferred to perform the heat treatment process for over 60 minutes in order to assure the more deeper zone depth without COP, it must be considered that the diffusion furnace can't be used for a long time.

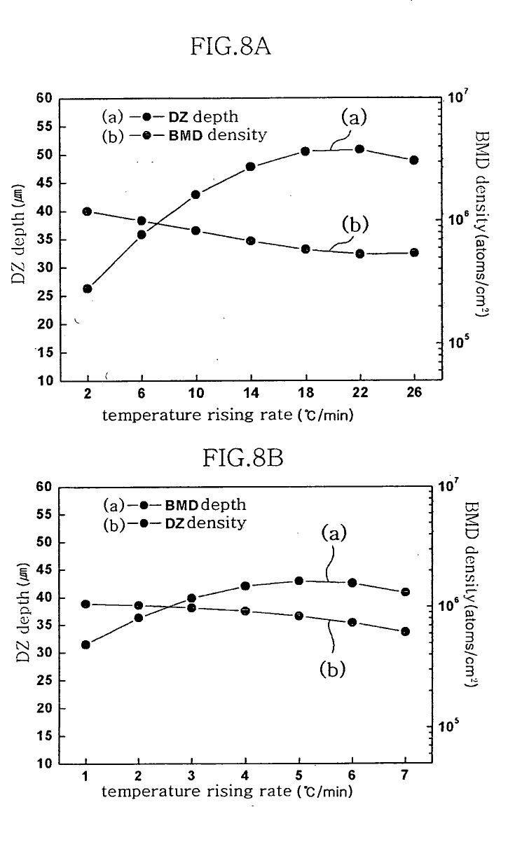

FIG. 8a is a diagram illustrating a denuded zone depth (corresponding to the part (a) in FIG. 8a) and a BMD density (corresponding to the part (b) in FIG. 8a) according to the temperature ramp-up rate (the first temperature ramp-up rate) during the period between the first temperature of 500° C. and the second temperature of 950° C. illustrated with reference to FIG. 2. During this time, the other conditions for the heat treatment are same to the case in FIG. 5. The DZ depth and BMD density are monitored after setting an oxygen concentration of 12.5 ppma, and the temperature ramp-up speed (the second temperature ramp-up rate) in 5° C./min during the period between the second temperature of 950° C. and the third temperature of 1100° C. illustrated with reference to FIG. 2. The DZ depth and BMD density are monitored by a method using a microscope. The measurement of DZ depth and BMD density is performed after two step heat treatments again (heat treatment processes for 4 hours at the temperature of about 800° C. and 16 hours at the temperature of about 1000° C.) in an oxygen atmosphere and the treatment of Secco etching. Under the oxygen atmosphere, as shown in FIG. 8a, as the temperature ramp-up rate (the first temperature ramp-up rate) is being increased, the DZ depth is also increased. But the DZ depth does not increase after the temperature ramp-up speed (the first temperature ramp-up rate) exceeds 18° C./min. On the other hand, the BMD density decreases proportionally to the temperature ramp-up rate up after it reaches 18° C./min. Furthermore, a DZ depth at least 25 μm and a BMD density at least 5×10⁵ ea/cm² are assured for the designated heat rates. If the temperature ramp-up rate is too fast, the oxygen nuclei can not easily grow into oxygen precipitates because of short heat up time. As a result of this, oxygen precipitates density is low and the size is small, therefore the oxygen precipitates are more easily removed from the surface during the 1200° C. heat treatment.

FIG. 8b is a diagram illustrating the denuded zone depth (corresponding to the part (b) in FIG. 8b) and the BMD density (corresponding to the part (a) in FIG. 8b) according to the temperature ramp-up speed (the second temperature ramp-up rate) during the period between the second temperature of 950° C. and the third temperature of 1100° C., after setting the temperature ramp-up speed (the first temperature ramp-up rate) during the period of the first temperature of 500° C. to the second temperature of 950° C. at 10° C./min, as illustrated with reference to FIG. 2. During this time period, the other conditions for the heat treatment are same to the case in FIG. 5. Although FIG. 8b shows the similar result to FIG. 8a, the DZ depth begins to diminish at over 5° C./min.

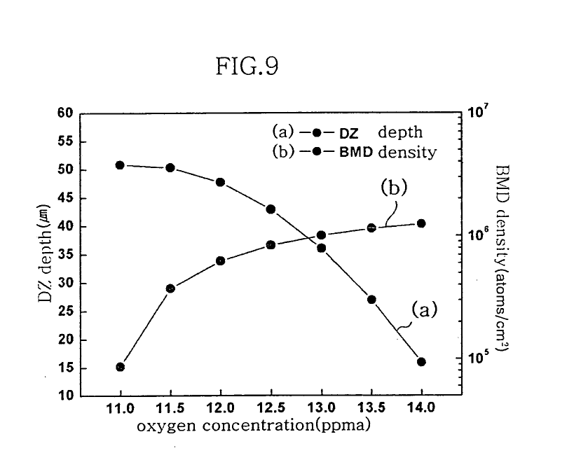

FIG. 9 is a diagram illustrating variations of denuded zone depth and bulk micro defect density according to oxygen concentration. The DZ depth and the BMD density are monitored after setting the temperature ramp-up speed (the first temperature ramp-up rate) at 10° C./min during the period between the first temperature of 500° C. and the second temperature of 950° C., and the temperature ramp-up speed (the second temperature ramp-up rate) at 5° C./min during the period between the second temperature of 950° C. and the third temperature of 1100° C., as illustrated with reference to FIG. 2. As described in FIG. 9, as the oxygen concentration is increased, the DZ depth (the part (a) in FIG. 9) is increased and the BMD density ((b) in FIG. 9) is decreased. As a result of this, it is noticed that the oxygen concentration has influence on the DZ depth and the BMD density more than the temperature ramp-up speed which has worked as a fixed factor. Accordingly, when the deep DZ depth and high BMD density should be assured at a low oxygen concentration, and the shallow DZ depth and low BMD density should be assured at a high oxygen concentration, it is possible to get above-mentioned properties by properly adjusting the temperature ramp-up speeds (the first and second temperature ramp-up rates). That is, the temperature ramp-up speeds (the first and second temperature ramp-up rates) can be increased/decreased for adjusting the DZ depth and BMD density according to the oxygen concentration required in a semiconductor device.

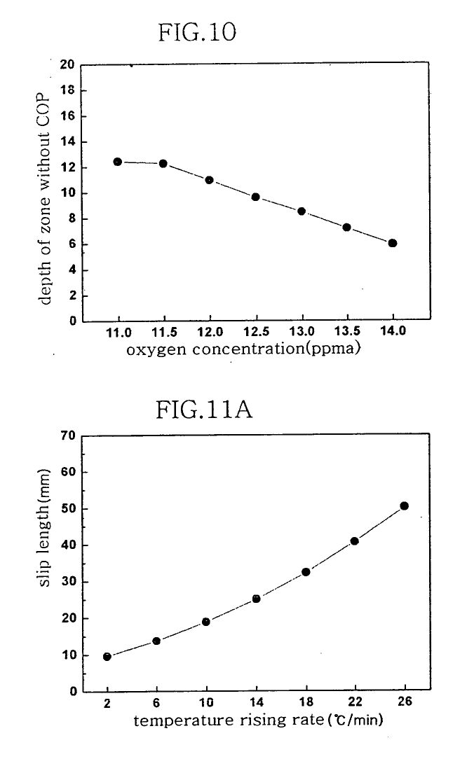

FIG. 10 shows the depth of a zone without COP according to the oxygen concentration of the nitrogen-doped silicon wafer. FIG. 10 has the same conditions to the heat treatment conditions illustrated with reference to FIG. 5, and the nitrogen is doped in concentration of 5×10¹³ atoms/cm³. As described in FIG. 10, when the oxygen concentration is increased, the zone depth without COP is decreased linearly. Here, when the oxygen concentration is 14 ppma, the defect free zone depth without COP is remarkably decreased to about 6 μm. However, as shown in FIG. 5, the defect free zone depth is increased when the heat treatment time is increased. In response to this, the zone depth (without COP) required in a semiconductor device can be satisfied by adjusting the heat treatment time at a low oxygen concentration.

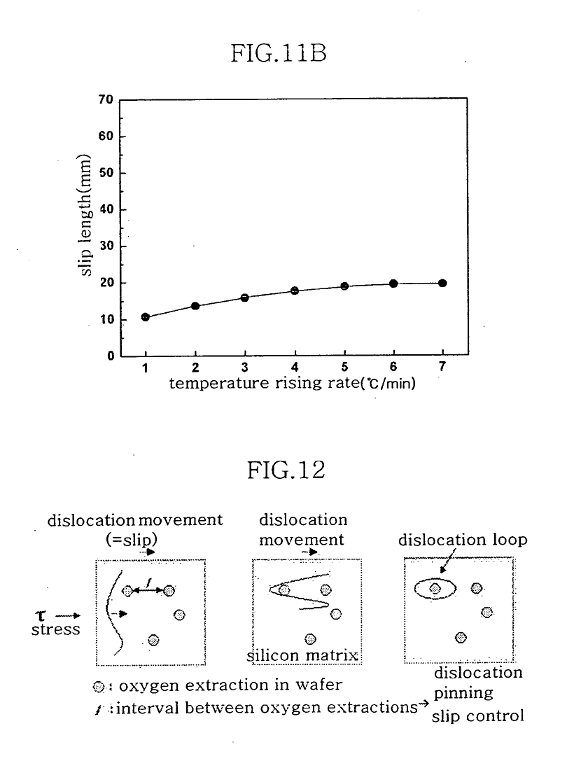

FIGS. 11a and 11b are diagrams illustrating the overall slip length according to the temperature ramp-up time. FIG. 11a shows variation of the slip length while fixing the second temperature ramp-up rate at 5° C./min and changing the first temperature ramp-up rate with reference to FIG. 2, and FIG. 11b shows variation of the slip length while fixing the first temperature ramp-up rate at 10° C./min and changing the second temperature ramp-up rate with reference to FIG. 2.

FIGS. 11a and 11b show results of performing the heat treatment process by fixing the heat treatment temperature at 1200° C., the heat treatment time for 60 minutes, and the oxygen concentration in 12.5 ppma. The other heat treatment conditions are same to the conditions illustrated with reference to FIG. 5. In general, when the temperature ramp-up speed is increased in the diffusion furnace, it results in increasing the temperature difference between the wafer center and wafer edge and the thermal stress thereby remarkably causes slip. As a result of this, the stress is occurred by the difference of heat expansion coefficient between the silicon and a silicon carbide (SiC) at the connected part between the silicon wafer and a silicon carbide (SiC) boat during a heating treatment, causing the slip thereby. That is, when the temperature ramp-up speed is increased, the slip length is increased thereby. It is shown that the slip length comes to be longer according to increase of the temperature ramp-up speed in both FIGS. 11a and 11b.

In general, when an external stress is occurred at the single-crystalline silicon grid, and this stress is pressed more than silicon yield stress, a variation thereby is defined as a strain or a dislocation. If the external stress is continually pressed, the dislocation moves among the grids, which is called as a slip. The slip does not come to easily generated in case that the movement of dislocation interfere with precipitates in the silicon wafer, in case that the density of precipitates increase and thus the intervals among the precipitates are narrow. The slip generation can be decreased by increasing the precipitate density in the wafer due to a dislocation pinning effect. It will be described the process that oxygen precipitates interrupt dislocation movement in the silicon wafer in FIG. 12.

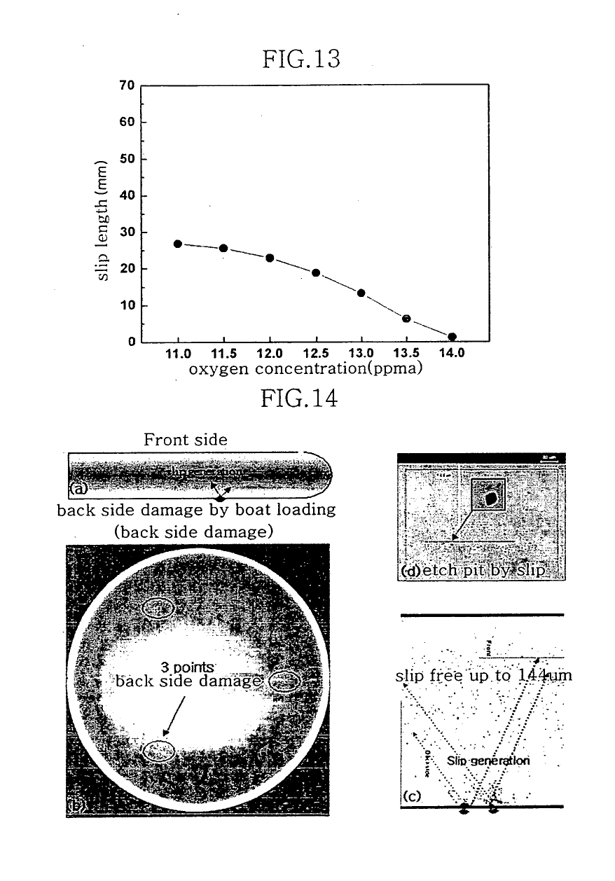

On the other hand, as illustrated in FIG. 9, when the oxygen concentration is increased, the BMD density, the oxygen precipitates in a bulk in also increased. That is, when the oxygen concentration is high, the oxygen precipitates density is also increased. FIG. 13 shows the slip length versus oxygen concentration after fixing the second temperature ramp-up rate at 5° C./min as illustrated in FIG. 2, and the first temperature ramp-up rate at 10° C./min. As illustrated in FIG. 13, when the oxygen concentration is increased, the slip generation is remarkably decreased. Here, when the oxygen concentration is 14 ppma, slip is rarely generated within 1 mm. However, when the oxygen concentration is increased, the DZ depth is relatively decreased, and thus it is not preferable at the side of assuring a sufficient DZ depth.

Therefore, it is advantageous that the oxygen concentration is as low as possible for assuring a sufficient DZ depth and a zone depth without COP, and the problem of slip generation thereby can be solved by properly adjusting the heat treatment conditions. According to the testing results in the embodiment, the slip happens below 1 mm when the first and second temperature ramp-up rates is set at 5° C./min at the same time at a low oxygen concentration of 11 ppma. FIG. 14 shows the monitoring result therefor by XRT.

It is impossible to control a damage shown by a point below 1 mm in general due to contact between the wafer and a boat during the heat treatment for manufacturing an annealed wafer. Therefore, it should be confirmed whether the slip transits from the damage-occurred area to a semiconductor device driving zone after two steps of device heat treatments (4 hours at 800° C. and 16 hours at 1000° C.). As shown in FIG. 14c, after device heating treatment, the slip transits from the surface to about 144 um, but it does not transit into the active region of device. Those results, as described in FIG. 14c, shows that the dislocation pinning effect by way of the high BMD density in the bulk prevents the slip from being transited to the active region of device.

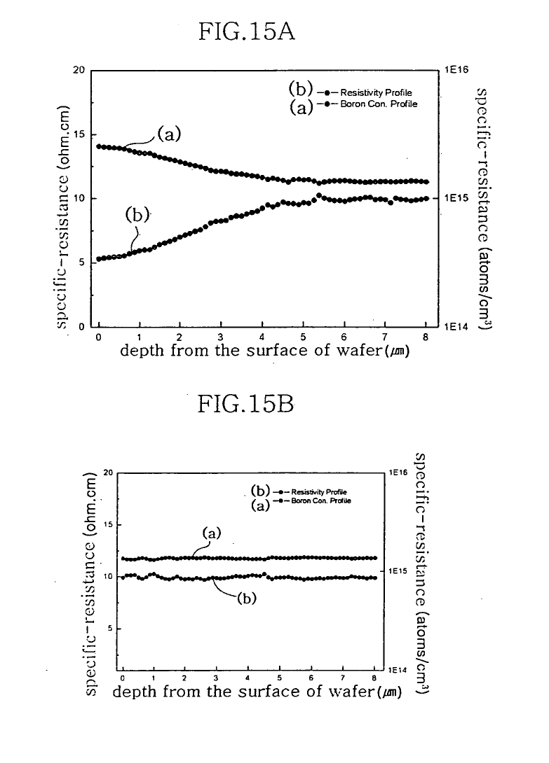

FIGS. 15a and 15b are diagrams illustrating variations of resistivity according to a gas atmosphere. FIG. 15a shows the variation of resistivity when the heat treatment is performed at the argon gas atmosphere at the period of the first to third temperatures illustrated with reference to FIG. 2. FIG. 15b shows the variation of resistivity when the heat treatment is performed at the hydrogen atmosphere at the period of the first to third temperatures. In general, in case of performing the heat treatment at the Ar atmosphere, a boron atom in clean-room is absorbed on the wafer surface, and thus diffused to the internal during the heat treatment. Accordingly, the density of boron atom is increased on the surface, as shown in FIG. 15a, and the boron atom is diffused to the internal during the heat treatment, decreasing the value of resistivity. Those phenomena have fatal influence on the device. Therefore, in order to solve the problem, a native oxide film on the wafer including the boron atom is eliminated completely by switching the hydrogen gas atmosphere into the argon gas atmosphere during heat treatment. As a result of this, the in-diffusion of boron atom is prevented during heat treatment and thus it makes available to get a uniform resistivity, as described in FIG. 15b.

As such, when the gas atmosphere is changed from the inert gas atmosphere to the hydrogen atmosphere, it is important for the temperature period of the heat treatment at the hydrogen atmosphere. The hydrogen should be added as small as completely eliminating the native oxide layer, but if adding more than that, it eliminates the native oxide film on the surface after that, the boron atom inside wafer reversely diffuse into the outside of wafer. As a result of this, the resistivity on the surface is rather increased. Furthermore, in case of performing the heat treatment at over 1100° C. for a long period of time, it causes increasing of metal contamination of the wafer. In general, in case of performing the heat treatment only at the Ar atmosphere, it has increased the life time of main consumable such as quartz more than in case of performing the heat treatment at the hydrogen atmosphere, and has been known as being advantageous in the side of wafer contamination. Accordingly, as described above, it is preferable to designate and control the heat treatment period properly at the hydrogen atmosphere.

According to the monitoring result, when the heat treatment is performed under a hydrogen atmosphere during the period between the first temperature of 500° C. and the third temperature of 1100° C., and performed under the argon atmosphere at the rest temperature period, it is possible to get a very uniform resistivity profile by eliminating only the native oxide layer including the boron atom on the wafer surface, as illustrated in FIG. 15b.

The disclosed methods can control the slip generation by a high-temperature process, which has been a problem of an annealed wafer. Furthermore, it is possible to provide a uniform and sufficient DZ zone and a zone without COP in an active region of device. Moreover, it is possible to manufacture a wafer with a uniform BMD and a high BMD density in the bulk zone between the denuded zones. Therefore, it is possible to increase the effect of gettering metal impurities such as Fe by forming a uniform and high density BMD under an active region of device.

Although the disclosed methods have been described in connection with certain embodiments and illustrated in the accompanying drawings, this disclosure is not limited thereto. It will be apparent to those skilled in the art that various substitutions, modifications and changes may be made thereto without departing from the scope and spirit of this disclosure.

What is claimed is:

1. A method of manufacturing a silicon wafer, comprising:
(a) preparing a silicon wafer having a front side, a rear side, and a zone interposed between the front side and the rear side;
(b) loading the silicon wafer into a heat treatment apparatus having a first temperature;
(c) pre-heating the silicon wafer at the first temperature for a predetermined time;
(d) heating the heat treatment apparatus to a second temperature higher than the first temperature at a first temperature ramp-up rate;
(e) heating the heat treatment apparatus to a third temperature higher than the second temperature at a second temperature ramp-up rate;
(f) heating the heat treatment apparatus to a fourth temperature higher than the third temperature at a third temperature ramp-up rate;
(g) heating the silicon wafer at the fourth temperature apparatus by maintaining the fourth temperature for a predetermined time; and
(h) cooling the heat treatment apparatus to about the first temperature;
wherein the second temperature ramp-up rate is smaller than the first temperature ramp-up rate; the parts (c), and (f) through (h) are carried out in an atmosphere of inert gas; and the parts (d) and (e) are carried out in an atmosphere of hydrogen.

2. The method of claim 1, wherein part (a) comprises:
dipping a seed crystal in a silicon melt and growing a single-crystal silicon ingot by pulling up the seed crystal with adjusting a crystal growing speed and a temperature gradient along a growing axis at a boundary of solid and liquid phase;
slicing the grown single-crystalline silicon ingot into shapes of wafers; and
removing slicing damages generated from slicing and rounding sides of the sliced wafer or etching a surface of the sliced wafer;
wherein the single-crystalline silicon ingot is grown with nitrogen doped in concentration ranging from about 1×10¹² atoms/cm³ to about 1×10¹⁴ atoms/cm³ to reduce energy required for creating nuclei and to increase precipitated oxygen micro-nuclei.

3. The method of claim 1, further comprising, after part (h):
polishing the surface of the silicon wafer;
making the surface of the silicon wafer specular; and
cleaning the silicon wafer.

4. The method of claim 1, wherein the first temperature is about 500° C.; the second temperature is about 950° C.; the third temperature is about 1100° C.; and the fourth temperature is about 1200° C.;

5. The method of claim 1, wherein the first temperature ramp-up rate is about 10° C./min; and the second temperature ramp-up rate is about 5° C./min.

6. The method of claim 1, wherein the third temperature ramp-up rate ranges from about 0.1 to about 5° C./min.

7. The method of claim 1, wherein the part (g) is carried out for a time period ranging from about 1 to about 120 minutes at the fourth temperature.

8. The method of claim 1, wherein part (h) comprises:
cooling the heat treatment apparatus down to the third temperature at a first temperature ramp-down rate;
cooling the heat treatment apparatus down to the second temperature at a second temperature ramp-down rate; and
cooling the heat treatment apparatus down to the first temperature at a third temperature ramp-down rate.

9. The method of claim 8, wherein the third temperature ramp-down rate is larger than the second temperature ramp-down rate.

10. The method of claim 8, wherein the first temperature ramp-down rate is in the range of from about 0.1 to about 5° C./min.

11. The method of claim 8, wherein the second temperature ramp-down rate is about 5° C./min; and the third temperature ramp-down rate is about 10° C./min.
